(19) United States
(12) Patent Application Publication
(10) Pub. No.: US 2015/0207347 A1
(43) Pub. Date: Jul. 23, 2015

(54) STORAGE BATTERY DEVICE

(71) Applicant: NEC ENERGY DEVICES, LTD., Kanagawa (JP)

(72) Inventors: Yuuki Hori, Kanagawa (JP); Shin Suzuki, Kanagawa (JP)

(73) Assignee: NEC ENERGY DEVICES, LTD., Kanagawa (JP)

(21) Appl. No.: 14/111,877

(22) PCT Filed: May 22, 2012
(86) PCT No.: PCT/JP2012/063036

§ 371 Date: Oct. 15, 2013

(30) Foreign Application Priority Data
May 25, 2011 (JP) 2011-116958

(51) Int. Cl. H02J 7/00; G01R 31/36

(52) U.S. Cl. CPC H02J 7/0021; G01R 31/3627; H02J 7/0052

(57) ABSTRACT

A voltage measurement unit (200) measures the voltage value between both ends of each of batteries (101-1) to (101-n). A control unit (300) determines whether or not the batteries (101-1) to (101-n) are defective based on the measured voltage values, outputs the series voltage of batteries (101-1) to (101-n) as the output voltage of a series body (100-1) if there is no battery, from among the batteries (101-1) to (101-n), that is determined to be defective, and outputs the boosted voltage from the voltage of the batteries (101-1) to (101-n) other than the battery that was determined to be defective as the output voltage of the series body (100-1).

### TECHNICAL FIELD

The present invention relates to a storage battery device having a plurality of batteries and a charging and discharging method in the storage battery device.

### BACKGROUND ART

Recently, environmental issues have attracted growing interest in various fields.

Among those, in the field of power supply, power supply by PV (Photo Voltanic) power generation, power supply utilizing secondary batteries for electric vehicles (EV: Electric Vehicle) and hybrid electric vehicles (HEV: Hybrid EV) and the like have been getting attention. As the secondary battery, the lithium ion secondary battery is regarded as the most likely candidate and expected to replace the lead storage battery with the spread in the future.

The storage battery element (storage battery) used as a secondary battery performs exchange of energy with the outside. Therefore, if the amount of energy to be exchanged becomes high, it is necessary to ensure battery safety by using protection circuits and the like.

Recently, in order to deal with the demand for high-voltage fields, multiple storage battery elements are connected in series to thereby gain high voltage.

As to storage battery elements connected in series, cases may occur in which the battery voltages of the storage battery elements differ from each other. This variation is caused by the different in characteristics between individual storage battery elements, the difference in temperature environment and the like. When storage battery elements that vary from each other are connected in series, the characteristic of the series body of batteries connected in series depends on the characteristic of the worst storage battery element.

To deal with this, techniques for making the voltage values of the storage batteries connected in series uniform have been tried (for example, see Patent Document 1).

### RELATED ART DOCUMENTS

### Patent Document

Patent Document 1: JP2009-540793A

### SUMMARY OF THE INVENTION

### Problems to be Solved by the Invention

Though it is possible by the technology disclosed in Patent Document 1 to reduce the possibility of occurrence of operation failure due to variation in the characteristics of storage battery elements, there is a problem that the technology cannot deal with a case where a part of storage battery elements has become deficient except for variation in characteristics.

In this case, the entire system including the series body becomes unusable, giving rise to a problem that all the battery elements have to be replaced by new ones in order to restore the battery.

The object of the present invention is to provide a storage battery device and a charging and discharging method for solving the above problems.

### Means for Solving the Problems

The storage battery device of the present invention is a storage battery device including a plurality of storage batteries, wherein

a plurality of series bodies, each formed of the multiple storage batteries being connected in series, are connected in parallel,

the series body comprises:

a voltage measurement unit for measuring the voltage value between both ends of each of the multiple storage batteries, and,

a control unit which determines whether or not the storage batteries are defective based on the voltage values measured by the voltage measurement unit and performs such control that if there is no storage battery that was determined to be defective, the series voltage of the multiple storage batteries is output as the output voltage of the series body whereas if there is a storage battery that was determined to be defective, the boosted voltage from the voltage of the batteries other than the defective battery is output as the output voltage.

The charging and discharging method of the present invention is a charging and discharging method for charging and discharging storage batteries in a storage battery device having a plurality of series bodies which are connected in parallel including a plurality of storage batteries connected in series, comprising the steps of:

measuring the voltage value between both ends of each of the multiple storage batteries;

determining whether or not the storage batteries are defective based on the measured voltage values;

outputting the series voltage of the multiple storage batteries as the output voltage of the series body if there is no storage battery that was determined to be defective; and,

outputting the boosted voltage from the voltage of the batteries other than the defective battery as the output voltage if there is a storage battery that was determined to be defective.

### Effect of the Invention

As has been described heretofore, according to the present invention, even if part of the storage batteries has become deficient, it is possible to continue charging and discharging, hence the life time of the system can be increased.

### BRIEF DESCRIPTION OF THE DRAWINGS

FIG. 1 is a diagram showing one exemplary embodiment of a storage battery device of the present invention

FIG. 2 is a diagram showing one example a threshold value stored in a storage unit shown in FIG. 1.

FIG. 3 is a diagram showing one example of an internal structure of a transformer shown in FIG. 1.

FIG. 4 is a table showing opening and closing states of switches in accordance with the conditions of batteries shown in FIG. 1.

FIG. 5 is a table showing opening and closing states of switches in accordance with the conditions of batteries shown in FIG. 1.

FIG. 6 is a diagram showing another exemplary embodiment of a storage battery device of the present invention.

FIG. 7 is a table showing opening and closing states of switches in accordance with the conditions of batteries shown in FIG. 6.

### MODE FOR CARRYING OUT THE INVENTION

Next, the exemplary embodiments of the present invention will be described with reference to the drawings.

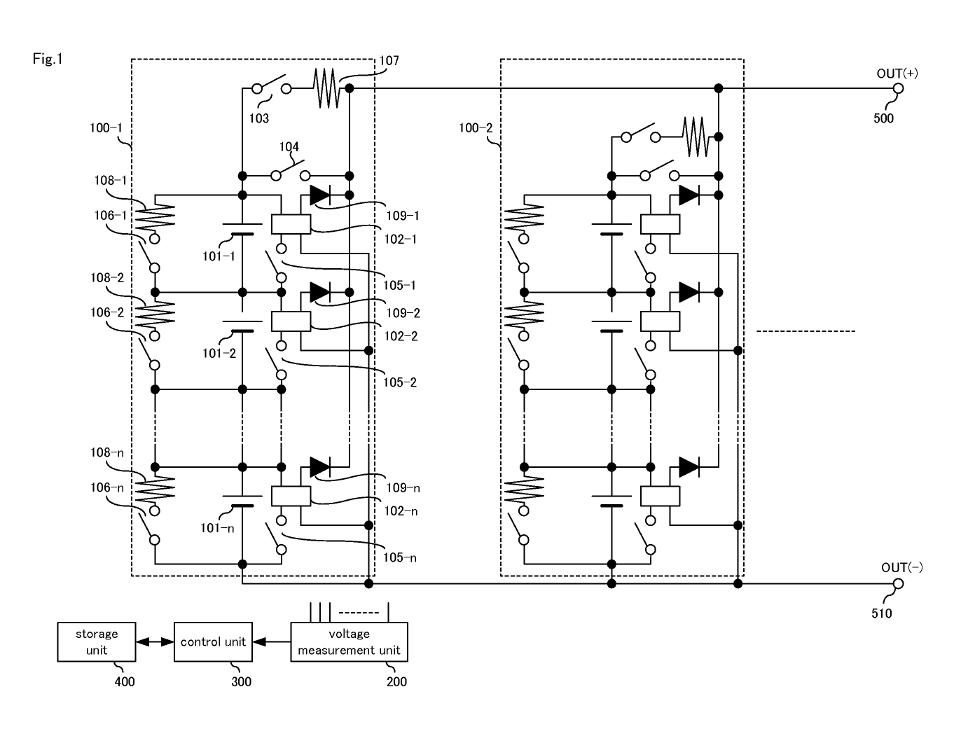

FIG. 1 is a diagram showing one exemplary embodiment of a storage battery device of the present invention.

As shown in FIG. 1, this exemplary embodiment includes a plurality of series bodies 100-1, 100-2, voltage measurement unit 200, control unit 300, storage unit 400, output terminal(+) 500, and output terminal(−) 510. Plural series bodies 100-1 and 100-2 are connected to each other in parallel. In FIG. 1, series body 100-1 and series body 100-2 alone are shown, but three or more series bodies may be connected to one another in parallel.

Series body 100-1 includes, as shown in FIG. 1, multiple storage batteries, i.e., batteries 101-1 to 101-n (n is a natural number equal to or greater than 2), transformers 102-1 to 102-n, switches 103, 104, 105-1 to 105-n, 106-1 to 106-n, resistors 107, 108-1 to 108-n, and diodes 109-1 to 109-n. The internal configuration of series body 100-2 is the same as that of series body 100-1.

Batteries 101-1 to 101-n are rechargeable storage batteries (storage battery elements). Batteries 101-1 to 101-n are lithium ion secondary batteries. Batteries 101-1 to 101-n are connected to each other in series.

Voltage measurement unit 200 measures the voltage value across each of batteries 101-1 to 101-n. Voltage measurement unit 200 outputs the measured voltage values to control unit 300. Voltage measurement unit 200 may be formed of a protective IC (Integrated Circuit) etc., and reads voltage across batteries 101-1 to 101-n by means of AD converters inside the IC.

Control unit 300 determines whether or not batteries 101-1 to 101-n are defective, based on the voltage values output from voltage measurement unit 200.

Herein, control unit 300 may compare the voltage value output from voltage measurement unit 200 with a predetermined threshold value and determine whether or not the battery is defective based on the result of comparison. For example, control unit 300 may be configured to determine that the battery is defective when the voltage value output from voltage measurement unit 200 is significantly lower than the threshold value or significantly higher than the threshold value.

For example, the control unit may be configured to determine that a battery is defective if the voltage across battery 101-1 to 101-n continues to be equal to or lower than 2V for 10 seconds or longer when batteries with a nominal capacity of 5 Ah, a nominal internal impedance of 3 mΩ and a maximum rate of 5 C are used as batteries 101-1 to 101-n. The voltage across the battery may momentarily lower to 2 V or below depending on the condition of discharging or other factors even if battery 101-1 to 101-n is normal. In such a case, use of the time average voltage makes it possible to avoid erroneous defective detection.

Alternatively, control unit 300 may be configured to compare the voltage values of batteries 101-1 to 101-n output from voltage measurement unit 200 and determine whether or not batteries are defective, based on the result of comparison. For example, control unit 300 may determine that a battery that has a voltage value that is widely different from the other voltage values is defective, among those of batteries 101-1 to 101-n output from voltage measurement unit 200.

An increase in the internal impedance of batteries 101-1 to 101-n indicates battery degradation. So, in order to detect the increase of impedance, it is possible to measure the voltage across each storage battery element during charging and discharging and calculate the median of the measurements in order to recognize that a storage battery element, in which the absolute value of the voltage difference from the median is equal to or greater than a predetermined value, is defective. For example, this predetermined value may be set at 75 mV (=5 Ah×5 C×3 mΩ). With this configuration, even if part of storage battery elements have become defective, anomaly current (cross current) arising between series bodies due to the defective storage battery element can be reduced to be equal to or lower than the current corresponding to the maximum rate of the storage battery element. Here, if the voltage distribution of the storage battery elements is symmetrical, the same detection can be done using the arithmetic mean value for the median.

Alternatively, control unit 300 may be configured to determine whether a battery is defective based on the degree of fluctuation (instability) of the voltage values of batteries 101-1 to 101-n output from voltage measurement unit 200. For example, control unit 300 may be configured such that if, from among batteries 101-1 to 101-n, there is a battery in which the degree of fluctuation of the voltage value output from voltage measurement unit 200 exceeds the predetermined range, the battery is considered to be defective.

Instead of determining whether or not batteries 101-1 to 101-n are defective based on the voltage values of batteries 101-1 to 101-n measured by voltage measurement unit 200, it is possible to provide a temperature measurement unit which measures the temperature of batteries 101-1 to 101-n and determines whether or not batteries 101-1 to 101-n are defective based on the measured temperatures. In this case, the control unit may be configured to determine that a battery is defective when the temperature measured by voltage measurement unit 200 is significantly higher than a predetermined threshold temperature (or may be stored in storage unit 400), when significantly lower (when equal to or higher than the predetermined value set at 70 deg.C, for example), when unstable, or when the temperature has abruptly risen or fallen. With this configuration, it is possible to prevent abnormal heating up of batteries 101-1 to 101-n. If it is difficult for the temperature measurement unit to measure the internal temperature of batteries 101-1 to 101-n, the temperature measurement unit may measure the external temperature of batteries 101-1 to 101-n. In other words, any temperature measurement unit is permissible as long as it measures temperature at a predetermined part of batteries 101-1 to 101-n.

It is also possible to determine whether or not batteries 101-1 to 101-n are defective based on both the voltage values measured by voltage measurement unit 200 and the temperatures measured by the temperature measurement unit.

When there is no battery which was determined to be defective from the above result of determination, control unit 300 outputs the series voltage across batteries 101-1 to 101-n as the output voltage of series body 100-1. On the other hand, when there is a battery which was determined to be defective, based on the above result, control unit 300 outputs the boosted voltage from the voltage of the batteries, other than the battery that was determined as a defective, as the output voltage of series body 100-1.

Specifically, when there is no battery which was determined as a defective in series body 100-1 based on the above result, control unit 300 disconnects transformers 102-1 to 102-n from series body 100-1. On the other hand, when there is a battery which was determined as a defective in series body 100-1, based on the above result, control unit 300 disconnects the battery that was determined as a defective and the transformer connected to that battery from series body 100-1 and boosts the output voltage of the batteries, other than the battery that was determined as a defective, using transformers 102-1 to 102-n and outputs the boosted voltage. That is, the discharge path of the battery that was determined as a defective is shut down.

In this way, if part of the batteries that constitute a series body has become defective, controller 300 disconnects the battery that was determined as a defective from the series body and boosts the voltage of the other batteries to be output, so that the series body in question can continue to discharge whilst remaining connected the other normal series bodies. As a result, it is possible to keep the battery device in operation without applying loads on the normal series bodies, compared to the case where part of the batteries for a series body being defective is cut off from the series body.

Storage unit 400 stores the threshold values to be used for the determination process of control unit 300 beforehand.

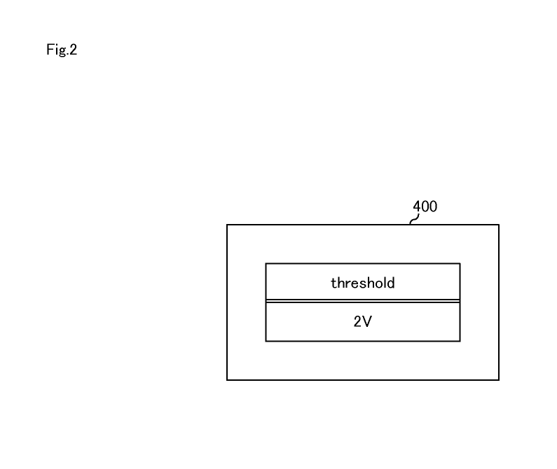

FIG. 2 is a diagram showing one example of a threshold value being stored in storage unit 400 shown in FIG. 1.

Storage unit 400 shown in FIG. 1 holds a threshold value to be used for the determination process, as shown in FIG. 2. For example, as shown in FIG. 2, a threshold value “2V” is stored. In this case, control unit 300 determines whether or not batteries 101-1 to 101-n are defective, using this threshold value.

Transformers 102-1 to 102-n are transformers (e.g., DC-DC converters or the like) that are connected to batteries 101-1 to 101-n, respectively so as to be able to boost the voltage of batteries 101-1 to 101-n. Transformers 102-1 to 102-n are each formed of two coils, the primary coil connected in parallel to corresponding battery 101-1 to 101-n and the secondary coil connected in parallel to series body 100-1. Here, though the term “coil” is used, the transformer does not need to be formed of coils as long as it can boost or step down the voltage applied on the primary side (on the left side in FIG. 1) and output the boosted or step-down voltage to the secondary side (the right side in FIG. 1).

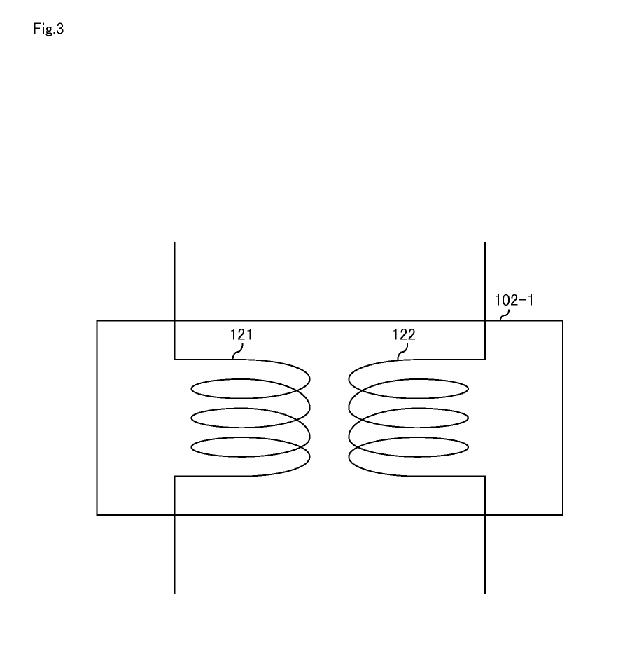

FIG. 3 is a diagram showing one example of an internal configuration of transformer 102-1 shown in FIG. 1.

As shown in FIG. 3, transformer 102-1 shown in FIG. 1 is a transformer formed of primary coil 121 and secondary coil 122. Transformer 102-1 boosts the voltage applied across primary coil 121 and outputs the boosted voltage to the secondary coil 122 side. The ratio of the number of turns in secondary coil 122 to that in the primary coil 121 is the number of batteries belonging to one series body 100-1 (n, in this case). That is, when the number of batteries is n, the ratio between the number of turns in the primary coil and that in the secondary coil is 1:n.

Transformers 102-1 to 102-n may be those that can variably convert the voltage value such as DCDC converters or the like.

Here, the internal configuration of transformers 102-2 to 102-n shown in FIG. 1 is the same as that of transformer 102-1 shown in FIG. 3.

Switch 103 is a current limiting path switch.

Switch 104 is a first discharge switch that is connected in series with batteries 101-1 to 101-n to switch connection (short-circuit)/disconnection under instructions from control unit 300.

Switches 105-1 to 105-n are second discharge switches that are connected in series with the primary coils of transformers 102-1 to 102-n, respectively, to switch connection (short-circuit)/disconnection under instructions from control unit 300.

Switches 106-1 to 106-n are switches that are connected in parallel with batteries 101-1 to 101-n, receptively to switch connection (short-circuit)/disconnection under instructions from control unit 300 at the time of charging batteries 101-1 to 101-n.

Herein, “connection (short-circuit)” is a state in which the switch is physically closed, and “disconnection” is a state in which the switch is physically open.

Control unit 300 performs the above-described control by instructing these switches to connect (short-circuit)/open. Specifically, when there is no battery that was determined to be defective at the time when batteries 101-1 to 101-n are being discharged, control unit 300 short-circuits switch 104 and opens all of switches 105-1 to 105n. On the other hand, when there is a battery that was determined to be defective at the time when batteries 101-1 to 101-n are being discharged, control unit 300 opens switch 104 and switch 105 that is connected to the primary coil of the transformer connected to the battery that was determined as a defective, and short-circuits the switches 105 connected to the primary coils of the transformers other than the former transformer. When there is no battery that was determined as a defective at the time when batteries 101-1 to 101-n are being discharged and being charged, control unit 300 opens switch 103. On the other hand, when there is a battery that was determined as a defective at the time when batteries 101-1 to 101-n are being discharged, control unit 300 opens switch 103. Further, when there is a battery that was determined to be defective at the time when batteries 101-1 to 101-n are being charged, control unit 300 short-circuits switch 103.

Further, when charging batteries 101-1 to 101-n, control unit 300 short-circuits switch 106 connected to the battery that was determined to be defective and opens switches 106 other than that. In a word, a bypass route is formed in order to ensure safety of the battery that was determined to be defective.

Moreover, control unit 300 may be configured to give notice to a predetermined device or perform a predetermined display in order that the system operator and others can recognize the above result of determination or the opening and closing operation of switches.

Resistor 107 is a current limiting resistor connected in series with switch 103. The set of switch 103 and resistor 107 may be replaced by a low current circuit that is made up of IGBT (Insulated Gate Bipolar Transistor), typical transistors and the like.

Resistors 108-1 to 108-n are bypass resistors connected in series with switches 106-1 to 106-n, respectively.

Diodes 109-1 to 109-n are each a reverse current protecting device connected in series with the secondary coil of respective transformer 102-1 to 102-n.

Here, switches 103, 104 and resistor 107 may be disposed on either the positive side or the negative side of series body 100-1.

Output terminal(+) 500 and output terminal(−) 510 are terminals that respectively output the positive potential and negative potential of series bodies 100-1 to 100-n.

Here, switches 103, 104, 105-1 to 105-n, and 106-1 to 106-n are switching devices such as MOS-FETs, transistors, and relays.

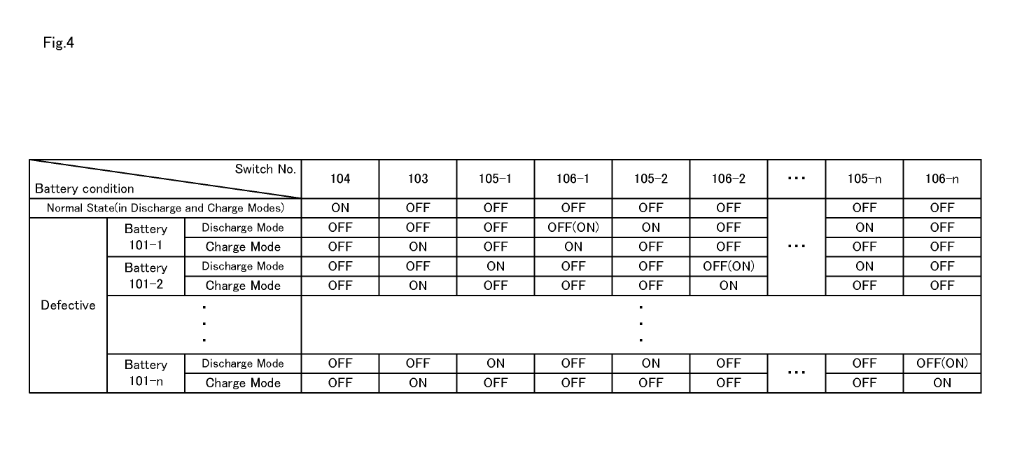

FIG. 4 is a table showing switching states in accordance with the conditions of batteries 101-1 to 101-n shown in FIG. 1.

In FIG. 4, the open(OFF) state and the closed(ON) state of switches 103, 104, 105-1 to 105-n, and 106-1 to 106-n in accordance with the conditions of batteries 101-1 to 101-n shown in FIG. 1, are shown and classified into those states at the time of discharging and at the time of charging.

When batteries 101-1 to 101-n are all normal, at the time of being discharged and at the time of being charged control unit 300 controls such that switch 104 is turned ON while the other switches 103, 105-1 to 105-n, 106-1 to 106-n are turned OFF.

When it is determined that battery 101-1 is defective at the time of being discharged, control unit 300 controls such that switches 105-2 to 105-n are turned ON while the other switches 103, 104, 105-1, 106-1 to 106-n are turned OFF. Herein, control unit 300 may control such that switch 106-1 is turned ON.

When it is determined that battery 101-1 is defective at the time of being charged, control unit 300 controls such that switches 103 and 106-2 to 106-n are turned OFF.

When it is determined that battery 101-2 is defective at the time of being discharged, control unit 300 controls such that switches 105-1, 105-3 (not shown) to 105-n are turned ON while the other switches 103, 104, 105-2, 106-1 to 106-n are turned OFF. Herein, control unit 300 may control such that switch 106-2 is turned ON.

When it is determined that battery 101-2 is defective at the time of being charged, control unit 300 controls such that switches 103 and 106-2 are turned ON while the other switches 104, 105-1 to 105-n, 106-1, 106-3 (not shown) to 106-n are turned OFF.

When it is determined that battery 101-n is defective at the time of being discharged, control unit 300 controls such that switches 105-1 to 105-(n−1) (not shown) are turned ON while the other switches 103, 104, 105-n, 106-1 to 106-n are turned OFF. Herein, control unit 300 may control such that switch 106-n is turned ON.

When it is determined that battery 101-n is defective at the time of being charged, control unit 300 controls such that switches 103 and 106-n are turned ON while the other switches 104, 105-1 to 105-n, 106-1 to 106-(n−1)(not shown) are turned OFF.

When there is a battery that was determined to be defective candidate in addition to determination of defective, the same procedure may be done. Defining the method of using defective candidates also makes it possible to increase the life time of the electricity storage system.

This defective candidate means one that is not defective but is going to be defective.

For example, any of batteries 101-1 to 101-n whose difference in voltage therebetween at the time of being charged and at the time of being discharged is equal to or greater than 45 mV and less than 75 mV may be regarded as a defective candidate. It is also possible to detect based on the voltage difference in open-circuit voltage from each other among batteries 101-1 to 101-n. In this case, similarly to detection of a defective, those presenting a voltage difference of 75 mV or greater may be regarded as a defective candidate. With this, it is possible to prevent occurrence of excessive cross current.

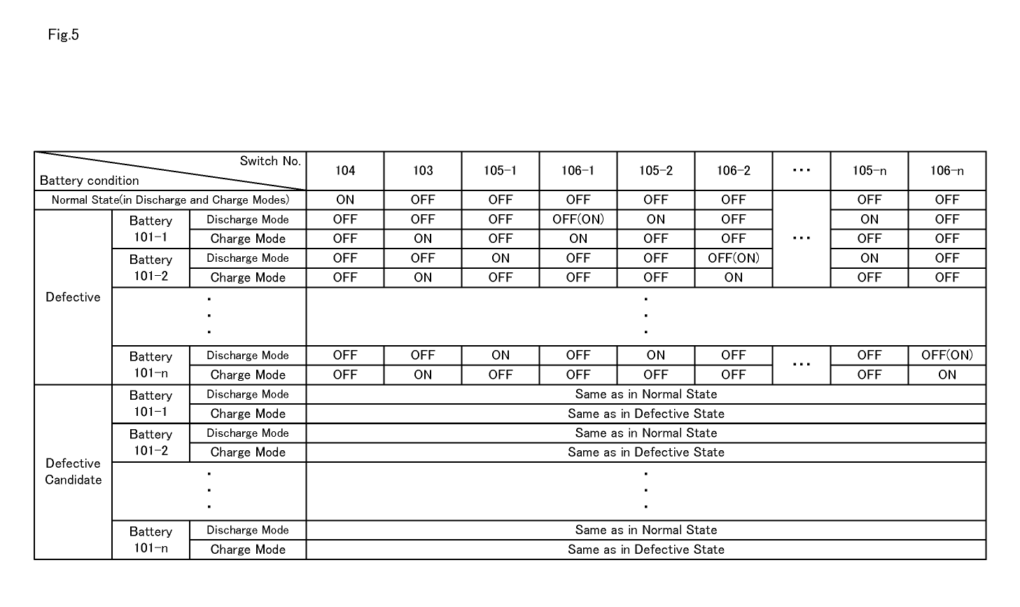

FIG. 5 is a table showing switching states in accordance with the conditions of batteries 101-1 to 101-n shown in FIG. 1.

In FIG. 5, the open(OFF) state and the closed(ON) state of switches 103, 104, 105-1 to 105-n, and 106-1 to 106-n in accordance with the conditions of batteries 101-1 to 101-n shown in FIG. 1, are shown and classified into those at the time of being discharged and at the time of being charged. Further, in FIG. 5, the conditions of batteries 101-1 to 101-n are shown with normal, defective, or defective candidate.

The open(OFF) and closed(ON) states of switches 103, 104, 105-1 to 105-n, and 106-1 to 106-n when the conditions of batteries 101-1 to 101-n are normal and defective are the same as those explained with FIG. 4.

When it is determined that battery 101-1 is a defective candidate at the time of being discharged, control unit 300 controls the switching states of switches 103, 104, 105-1 to 105-n and 106-1 to 106-n in the same manner when the conditions are normal.

When it is determined that battery 101-1 is a defective candidate at the time of being charged, control unit 300 controls the switching states of switches 103, 104, 105-1 to 105-n and 106-1 to 106-n in the same manner when the condition of battery 101-1 is determined to be defective.

When it is determined that battery 101-2 is a defective candidate at the time of being discharged, control unit 300 controls the switching states of switches 103, 104, 105-1 to 105-n and 106-1 to 106-n in the same manner when the conditions are normal.

When it is determined that battery 101-2 is a defective candidate at the time of being charged, control unit 300 controls the switching states of switches 103, 104, 105-1 to 105-n and 106-1 to 106-n in the same manner when the condition of battery 101-2 is determined to be defective.

When it is determined that battery 101-n is a defective candidate at the time of being discharged, control unit 300 controls the switching states of switches 103, 104, 105-1 to 105-n and 106-1 to 106-n in the same manner when the conditions are normal.

When it is determined that battery 101-n is a defective candidate at the time of being charged, control unit 300 controls the switching states of switches 103, 104, 105-1 to 105-n and 106-1 to 106-n in the same manner when the condition of battery 101-n is determined to be defective.

With this control it is possible to exclude storage battery elements that are highly likely to become defective, beforehand.

Further, the transformers may be those that can boost or step down voltage in both directions.

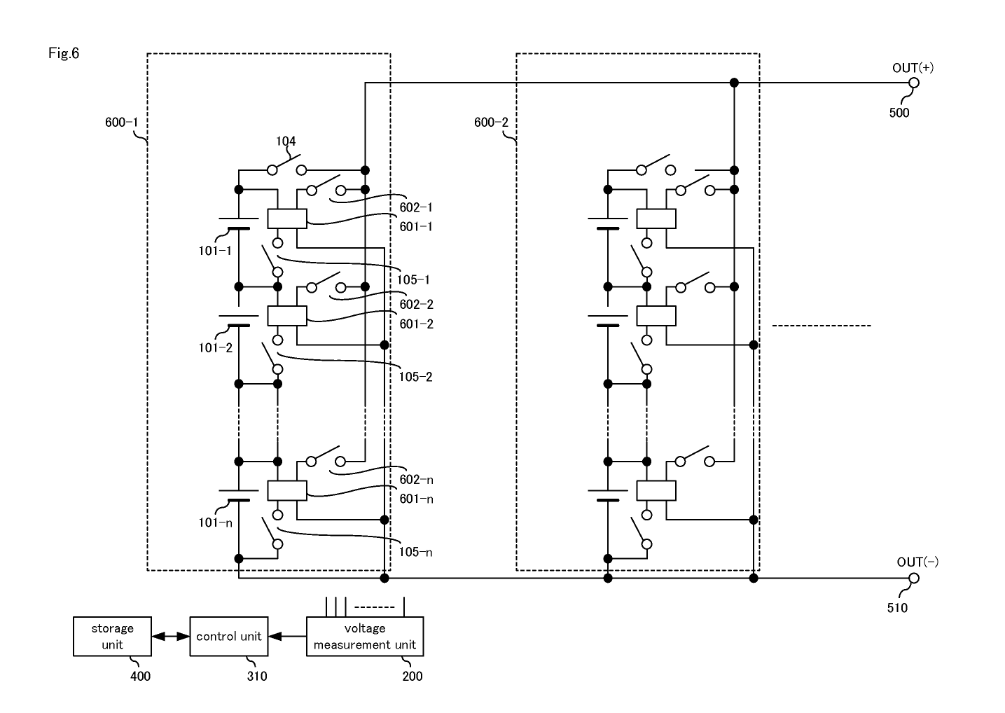

FIG. 6 is a diagram showing another exemplary embodiment of a storage battery device of the present invention.

As shown in FIG. 6, this embodiment includes a plurality of series bodies 600-1, 600-2, voltage measurement unit 200, control unit 310, storage unit 400, output terminal(+) 500, and output terminal(−) 510. Plural series bodies 600-1 and 600-2 are connected to each other in parallel. In FIG. 6, series body 600-1 and series body 600-2 alone are shown, but three or more series bodies may be connected to one another in parallel.

Voltage measurement unit 200, storage unit 400, output terminal(+) 500 and output terminal(−) 510 are the same as those in FIG. 1.

Series body 600-1 includes, as shown in FIG. 6, multiple storage batteries, i.e., batteries 101-1 to 101-n, transformers 601-1 to 601-n, switches 104, 105-1 to 105-n, and 602-1 to 602-n. Here, the internal configuration of series body 600-2 is the same as that of series body 600-1.

Batteries 101-1 to 101-n, and switches 104, 105-1 to 105-n are the same as those shown in FIG. 1. In the embodiment shown in FIG. 6, switch 104 is the third discharge switch and switches 105-1 to 105-n are the fourth discharge switches.

Transformers 601-1 to 601-n are transformers (e.g., DC-DC converters or the like) that are connected to batteries 101-1 to 101-n, respectively so as to be able to boost or step down voltage in both directions. Transformers 601-1 to 601-n are each formed of two coils, the primary coil connected in parallel to corresponding battery 101-1 to 101-n and the secondary coil connected in parallel to series body 600-1. Here, though the term “coil” is used, the transformer does not need to be formed of coils as long as it can boost or step down the voltage applied on the primary side (on the left side in FIG. 6) and output the boosted or step-down voltage to the secondary side (the right side in FIG. 6) and can boost or step down the voltage applied on the secondary side and output the boosted or step-down voltage to the primary side.

Switches 602-1 to 602-1 are the fifth discharge switches that are each connected in series with the secondary coil of corresponding transformer 601-1 to 601-n.

Control unit 310 determines whether or not batteries 101-1 to 101-n are defective, based on the voltage values output from voltage measurement unit 200. The criteria for determination may be the same as those in control unit 300 shown in FIG. 1.

When there is no battery which is determined to be defective from the above result of determination, control unit 310 outputs the series voltage across batteries 101-1 to 101-n as the output voltage of series body 600-1. On the other hand, when there is a battery which was determined to be defective from the above result of determination, control unit 310 outputs the boosted voltage from the voltage of the batteries other than the battery that was determined to be defective, as the output voltage of series body 600-1.

Specifically, when there is no battery which was determined to be defective in series body 600-1 from the above result of determination, control unit 310 disconnects transformers 601-1 to 601-n from series body 600-1. On the other hand, when there is a battery which was determined to be defective in series body 600-1 from the above result of determination, control unit 310 disconnects the battery that was determined to be defective and the transformer connected to that battery from series body 600-1 and boosts the output voltage of the batteries other than the battery that was determined to be defective, using transformers 601-1 to 601-n and outputs the boosted voltage. That is, the charge and discharge path of the battery that was determined to be defective is shut down.

Control unit 310 performs the above-described control by instructing these switches to connect (short-circuit)/open. Specifically, when there is no battery that was determined to be defective, control unit 310 short-circuits switch 104 and opens all of switches 105-1 to 105n and 602-1 to 602-n. On the other hand, when there is a battery that was determined as a defective, control unit 310 opens switch 104 and the switches 105 and 602 that are respectively connected to the primary coil and the secondary coil of the transformer connected to the battery that was determined to be defective, and short-circuits the switches 105 and 602 connected to the primary coils and secondary coils of the transformers other than the former transformer.

Moreover, control unit 310 may be configured to give notice to a predetermined device or perform a predetermined display in order that the system operator and others can recognize the above result of determination and the opening and closing operation of switches.

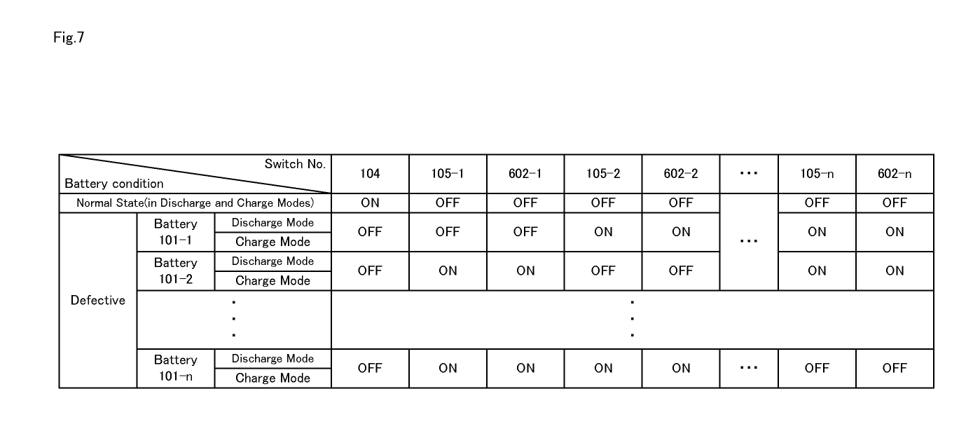

FIG. 7 is a table showing switching states in accordance with the conditions of batteries 101-1 to 101-n shown in FIG. 6.

In FIG. 7, the open(OFF) state and the closed(ON) state of switches 104, 105-1 to 105-n, and 602-1 to 602-n in accordance with the conditions of batteries 101-1 to 101-n shown in FIG. 6, are shown and classified into those at the time of being discharged and at the time of being charged.

When batteries 101-1 to 101-n are all normal, at the time of being discharged and at the time of being charged, control unit 310 controls such that switch 104 is turned ON while the other switches 105-1 to 105-n, 602-1 to 602-n are turned OFF.

When it is determined that battery 101-1 is defective, at the time of being discharged and at the time of being charged, control unit 310 controls such that switches 104, 105-1 and 602-1 are turned OFF while the other switches 105-2 to 105-n and 602-2 to 602-n are turned ON.

When it is determined that battery 101-2 is defective, at the time of being discharged and at the time of being charged, control unit 310 controls such that switches 104, 105-2 and 602-2 are turned OFF while the other switches 105-1, 105-3 (not shown) to 105-n, 602-1 and 602-3 (not shown) to 602-n are turned ON.

When it is determined that battery 101-n is defective, at the time of being discharged and at the time of being charged, control unit 310 controls such that switches 104, 105-n and 602-2 are turned OFF while the other switches 105-1 to 105-(n−1) (not shown), 602-1 to 602-(n−1) (not shown) are turned ON.

Instead of allotting one transformer for one battery, battery groups may be formed of multiple batteries so that one transformer is allotted for each battery group.

Here, the voltage values and temperature to be the criteria for detection of defectives and candidates may be changed as appropriate depending on the material and voltage range of storage battery elements.

As described heretofore, instead of cutting off the whole series body including a battery that was determined to be defective, the defective battery alone is cut off and the other batteries are used for output by boosting voltage. Accordingly, instead of being disqualified, the series body including the defective battery can be used as an auxiliary for the other normal series bodies. As a result, it becomes possible to prevent a marked lowering of the system capacity, reduce the number of times of changing a new battery, and inhibit degradation due to rate increase of the remaining series bodies, thus making it possible to lengthen the life of the whole system. Further, even if part of the batteries has become deficient, it is possible to keep the system running without stoppage.

Further, by cutting off a battery that was determined to be defective, it is possible to prevent the battery from exerting adverse influence on the other normal batteries.

Although the present invention has been explained with reference to the exemplary embodiments, the present invention should not be limited to the above exemplary embodiments of the invention. Various modifications that can be understood by those skilled in the art may be made to the structure and details of the present invention within the scope of the present invention.

This application claims priority based on Japanese Patent Application No. 2011-116958, filed on May 25, 2011, and incorporates all the disclosure thereof herein.

1. A storage battery device including a plurality of storage batteries, wherein
a plurality of series bodies, each formed of the multiple storage batteries being connected in series, are connected in parallel,
the series body comprises:
a voltage measurement unit for measuring the voltage value between both ends of each of the multiple storage batteries, and,
a control unit which determines whether or not the storage batteries are defective based on the voltage values measured by the voltage measurement unit and performs such control that if there is no storage battery that was determined to be defective, the series voltage of the multiple storage batteries is output as the output voltage of the series body whereas if there is a storage battery that was determined to be defective, the boosted voltage from the voltage of the batteries other than the defective battery is output as the output voltage.

2. The storage battery device according to claim 1, characterized in that
the series body includes a plurality of transformers which, each having the primary coil connected in parallel to each of the multiple storage batteries and the secondary coil connected in parallel to the series body in each of a plurality of storage batteries,
the control unit, when there is no storage battery that was determined to be defective, disconnects the multiple transformers from the series body, and when there is a storage battery that was determined to be defective, disconnects the storage battery and the transformer that is connected to the storage battery from the series body and boosts the output voltage of the storage batteries other than the defective battery using the transformers and outputs the boosted voltage.

3. The storage battery device according to claim 2, characterized in that
the series body comprises:
a first discharge switch connected in series with the storage batteries; and,
a plurality of second discharge switches each connected in series with the primary coil of each of the multiple transformers,
at the time of being discharged, the control unit, when there is no storage battery that was determined to be defective, short-circuits the first discharge switch and opens all the second discharge switches, and when there is a storage battery that was determined to be defective, opens the first discharge switch and the second discharge switch connected to the primary coil of the transformer that is connected to the storage battery that was determined to be defective and short-circuits the secondary discharge switches connected to the primary coil of the transformers other than the transformer that is connected to the storage battery that was determined to be defective.

4. The storage battery device according to claim 2, characterized in that
the series body comprises a plurality of charging switches connected in parallel with each of the multiple storage batteries, and
the control unit, at the time of charging the storage batteries, short-circuits the charging switch connected to the battery determined to be defective and opens the charging switches other than that.

5. The storage battery device according to claim 2, characterized in that the transformer can boost or step down voltage in both directions.

6. The storage battery device according to claim 5, characterized in that
the series body comprises a third discharge switch connected in series with the storage batteries, a plurality of fourth discharge switches each connected in series with the primary coil of each of the multiple transformers, and a plurality of fifth discharge switches each connected in series with the secondary coil of each of the multiple transformers,
the control unit, when there is no storage battery that was determined to be defective, short-circuits the third discharge switch and opens all the fourth discharge switches and the fifth discharge switches, and when there is a storage battery that was determined to be defective, opens the third discharge switch and the fourth discharge switch and the fifth discharge switch which are respectively connected to the primary coil and the secondary coil of the transformer that is connected to the storage battery that was determined to be defective and short-circuits the fourth discharge switches and fifth discharge switches connected to the primary coil and secondary coil of the transformers other than the transformer that is connected to the storage battery that was determined to be defective.

7. The storage battery device according to claim 2, characterized in that the ratio of the number of turns in the secondary coil to that in the primary coil is the number of batteries belonging to one series body.

8. The storage battery device according to claim 1, characterized in that the control unit compares the voltage value measured by the voltage measurement unit with a predetermined threshold value and determines whether or not the battery is defective based on the result of comparison.

9. The storage battery device according to claim 1, characterized in that the control unit compares the voltage values of the multiple storage batteries measured by the voltage measurement unit and determines whether or not the storage batteries are defective based on the result of comparison.

10. The storage battery device according to claim 4, characterized in that the control unit, at the time of charging the storage batteries, determines whether or not the storage batteries are defective candidates based on the voltage values measured by the voltage measurement unit, and short-circuits the charging switch connected to the storage battery that was detected as a defective candidate and opens the charge switches other than that.

11. The storage battery device according to claim 10, characterized in that the control unit compares the voltage values of the multiple storage batteries measured by the voltage measurement unit and determines whether or not the storage batteries are defective candidates based on the result of comparison.

12. The storage battery device according to claim 1, characterized in that the storage battery is a lithium ion secondary battery.

13. A charging and discharging method for charging and discharging storage batteries in a storage battery device having a plurality of series bodies which are connected in parallel including a plurality of storage batteries connected in series, comprising the steps of:
measuring the voltage value between both ends of each of the multiple storage batteries;
determining whether or not the storage batteries are defective based on the measured voltage values;
outputting the series voltage of the multiple storage batteries as the output voltage of the series body if there is no storage battery that was determined to be defective; and,
outputting the boosted voltage from the voltage of the batteries other than the defective battery as the output voltage if there is a storage battery that was determined to be defective.
